(19) United States
(12) Patent Application Publication
(10) Pub. No.: US 2024/0168372 A1
(43) Pub. Date: May 23, 2024

(54) METHOD, APPARATUS, AND SYSTEM WITH RESIST IMAGE ESTIMATION

(71) Applicant: SAMSUNG ELECTRONICS CO., LTD., Suwon-si (KR)

(72) Inventors: Deokyoung KANG, Suwon-si (KR); Youngchul KWAK, Suwon-si (KR); Serim RYOU, Suwon-si (KR); Seong-Jin PARK, Suwon-si (KR); Seon Min RHEE, Suwon-si (KR); Jaewon YANG, Suwon-si (KR); Eunju KIM, Suwon-si (KR); Hyeok LEE, Suwon-si (KR)

(73) Assignee: SAMSUNG ELECTRONICS CO., LTD., Suwon-si (KR)

(21) Appl. No.: 18/518,551

(22) Filed: Nov. 23, 2023

(30) Foreign Application Priority Data
Nov. 23, 2022 (KR) 10-2022-0158629
Oct. 10, 2023 (KR) 10-2023-0134431

(51) Int. Cl. G03F 1/72; G06T 7/564

(52) U.S. Cl. CPC G03F 1/72; G06T 7/564; G06T 2207/10032; G06T 2207/10061; G06T 2207/20081; G06T 2207/20084; G06T 2207/30148

(57) ABSTRACT

A method and apparatus for estimating a resist image (RI) are disclosed. The method includes obtaining an aerial image (AI) and a first RI from a mask image (MI), obtaining a second RI from the AI, and obtaining a third RI based on the first RI and the second RI.

### CROSS-REFERENCE TO RELATED APPLICATIONS

This application claims the benefit under 35 USC § 119(a) of Korean Patent Application No. 10-2022-0158629, filed on Nov. 23, 2022, and Korean Patent Application No. 10-2023-0134431, filed on Oct. 10, 2023 in the Korean Intellectual Property Office, the entire disclosure of which is incorporated herein by reference for all purposes.

### BACKGROUND

### 1. Field

The following description relates to a method, apparatus, and system with resist image (RI) estimation.

### 2. Description of Related Art

Photolithography refers to a process of depositing a photoresist on a wafer surface, separating a portion in which a circuit is to be patterned and a portion in which a circuit is not to be patterned, and exposing the photoresist using an electron gun. In additional aspects of a typical photolithography process, portions of the circuit pattern may be removed by an exposure to a light.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a processor-implemented method including generating an aerial image and a first resist image using a first model provided a first input based on, based on a mask image, generating a second resist image using a second model provided a second input based on the aerial image, generating a third resist image based on the first resist image and the second resist image, generating a resist contour image (RCI) using a third model provided a third input based on the third resist image, and training the second model based on a difference between the RCI and a measurement contour image.

The second input may be based on the aerial image and the mask image.

The method may include training the first model based on the difference between the RCI and the measurement contour image.

The training of the second model may include training the second model so that the difference between the RCI and the measurement contour image is minimized through backpropagation based adjustments of parameters of the second model.

The training of the second model may include iteratively adjusting a parameter and a coefficient of a kernel of the second model.

The second model may include one of a free-form kernel, a regularized kernel generated based on a Gabor filter, and a multiple-layered convolutional neural network (CNN).

The method may include training the third model based on the third resist image and the measurement contour image.

Parameters of the third model may be fixed during the training of the second model.

The third model may include a CNN-based model configured to receive the third resist image and generate the RCI.

In a general aspect, here is provided a non-transitory computer-readable storage medium storing instructions that, when executed by a processor, cause the processor to perform the method.

In a general aspect, here is provided a processor-implemented method including generating an aerial image and a first resist image using a first model provided a first input, based on a mask image, the first model comprising a first kernel, generating a second resist image using a second model provided a second input based on the aerial image, the second model comprising a second kernel, and generating a third resist image using a third model provided a third input based on the first resist image and the second resist image, and the second model is trained based on a difference between the third resist image and a measurement contour image.

In a general aspect, here is provided an electronic device including a processor configured to execute a plurality of instructions and a memory storing the plurality of instructions, wherein execution of the plurality of instructions configures the processor to: generate an aerial image and a first resist image using a first model provided a first input, based on a mask image, generate a second resist image using a second model provided a second input based on the aerial image, generate a third resist image using a third model provided a third input based on the first resist image and the second resist image, generate a resist contour image (RCI) by inputting the third resist image to a third model, and train the second model based on a difference between the RCI and a measurement contour image.

The second input may be based on the aerial image and the mask image.

The processor may be configured to train the first model based on the difference between the RCI and the measurement contour image.

The processor may be configured to train the second model so that the difference between the RCI and the measurement contour image is minimized through backpropagation based adjustments of parameters of the second model.

The processor may be configured to iteratively adjust a parameter and a coefficient of a kernel of the second model.

The second model may be one of a free-form kernel, a regularized kernel generated based on a Gabor filter, and a multiple-layered convolutional neural network (CNN).

The processor may be configured to train the third model based on the third resist image and the measurement contour image.

Parameters of the third model may be fixed during the training of the second model.

The third model may include a CNN-based model configured to receive the third resist image and generate the RCI.

In a general aspect, here is provided an electronic device including a processor configured to execute a plurality of instructions and a memory storing the plurality of instructions, wherein execution of the plurality of instructions configures the processor to be configured to generating, by an additional kernel model, a second resist image based on initial images received from a compact model, generating, by the compact model, a third resist image based on the second resist image and the initial images, generating, by a contour model, a resist contour image (RCI) based on the third resist image.

The second resist image may include a residual resist image.

The initial images include an aerial image and a first resist image derived from a mask image.

The processor may be configured to receive a scanning electron microscope image of a contour image of a resist.

The processor may be configured to train the additional kernel model based on a difference between the RCI and the contour image.

In one general aspect, a method of estimating a resist image (RI) includes obtaining an aerial image (AI) and a first RI from a mask image (MI), obtaining a second RI by inputting the AI to an additional kernel model, and obtaining a third RI based on the first RI and the second RI, wherein the third RI includes shape information of a pattern formed on a wafer that is generated by the MI.

The obtaining of the AI and the first RI may include obtaining the AI and the first RI by inputting the MI to a compact model.

The obtaining of the third RI may include obtaining the third RI by combining the first RI with the second RI.

The additional kernel model may be trained based on a difference between a resist contour image (RCI) generated based on the third RI and a measurement contour image generated through measurement.

The additional kernel model may be trained so that the difference is minimized through backpropagation.

The method may further include obtaining a predicted mask layout based on the third RI and correcting a mask layout based on a difference between the predicted mask layout and a target mask layout.

The obtaining of the predicted mask layout may further include generating an RCI from the third RI and obtaining the predicted mask layout based on the RCI.

The correcting of the mask layout may further include correcting the mask layout based on the difference between the predicted mask layout and the target mask layout and obtaining a mask layout image that is rasterized from the corrected mask layout.

The method may further include generating an MI in which a three-dimensional (3D) element is reflected by inputting the mask layout image to a mask model.

In another general aspect, a method of manufacturing a mask includes obtaining a resist image (RI) by inputting a mask image (MI) to an RI estimation model, obtaining a predicted mask layout based on the RI, and correcting a mask layout based on a difference between the predicted mask layout and a target mask layout, wherein the RI includes shape information of a pattern formed on a wafer that is generated by the MI.

In still another general aspect, an electronic device includes a memory storing at least one instruction and a processor configured to, by executing the at least one instruction stored in the memory, obtain an AI and a first RI from an MI, obtain a second RI by inputting the AI to an additional kernel model, and obtain a third RI based on the first RI and the second RI, wherein the third RI includes shape information of a pattern formed on a wafer that is generated by the MI.

The processor may be configured to obtain the AI and the first RI by inputting the MI to a compact model.

The processor may be configured to obtain the third RI by combining the first RI with the second RI.

The additional kernel model may be trained based on a difference between an RCI generated based on the third RI and a measurement contour image generated through measurement.

The additional kernel model may be trained so that the difference is minimized through backpropagation.

The processor may be configured to obtain a predicted mask layout based on the third RI and correct a mask layout based on a difference between the predicted mask layout and a target mask layout.

The processor may be configured to generate the RCI from the third RI and obtain the predicted mask layout based on the RCI.

The processor may be configured to correct the mask layout based on the difference between the predicted mask layout and the target mask layout and obtain a mask layout image that is rasterized from the corrected mask layout.

The processor may be configured to generate an MI in which a 3D element is reflected by inputting the mask layout image to a mask model.

Other features and aspects will be apparent from the following detailed description, the drawings, and the claims.

### BRIEF DESCRIPTION OF THE DRAWINGS

FIG. 1 illustrates an example compact model forming a resist image (RI) according to one or more embodiments.

FIG. 2A illustrates an example method using a neural network (NN) according to one or more embodiments.

FIG. 2B illustrates an example system for estimating an RI according to one or more embodiments.

FIG. 3 illustrates an example method of training a feed forward model according to one or more embodiments.

FIG. 4 illustrates an example method of estimating an RI according to one or more embodiments.

FIGS. 5A and 5B illustrate example kernels of an additional kernel model according to one or more embodiments.

FIG. 6 illustrates an example method according to one or more embodiments.

FIG. 7 illustrates an example configuration of an electronic device according to one or more embodiments.

FIG. 8A illustrates an example of a method of estimating an RI.

FIGS. 8B and 8C illustrate examples of a method of manufacturing a mask.

FIG. 9 illustrates an example of a method of manufacturing a mask.

FIG. 10 illustrates an example of a configuration of an electronic device.

Throughout the drawings and the detailed description, unless otherwise described or provided, the same, or like, drawing reference numerals may be understood to refer to the same, or like, elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Due to manufacturing techniques and/or tolerances, variations of the shapes shown in the drawings may occur. Thus, the examples described herein are not limited to the specific shapes shown in the drawings, but include changes in shape that occur during manufacturing.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

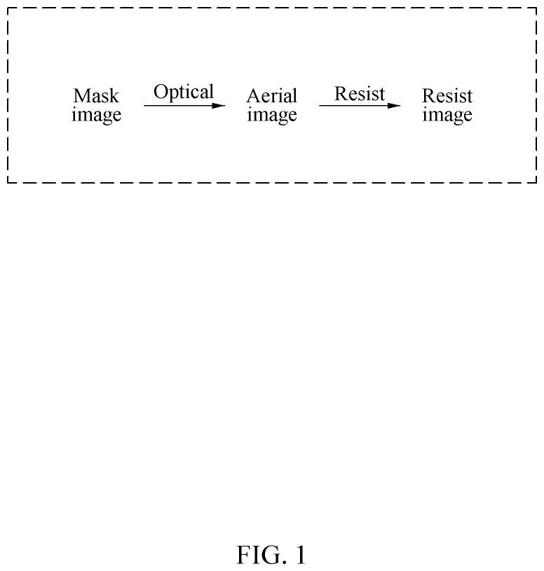

FIG. 1 illustrates an example compact method of forming a resist image (RI) according to one or more embodiments.

In an example, a typical process of forming a semiconductor may include several processes being performed in a predetermined order. Example processes may include a wafer manufacturing process, an oxidation process, a photolithography process, an etching process, deposition and ion implantation processes, a metal wiring process, an electrical die sorting (EDS) process, and a packaging process.

The photolithography process forms a pattern for a semiconductor circuit where the circuit design is created on a wafer. A photosensitive layer is applied on the wafer and then a mask is placed over the photosensitive layer. The photolithography process uses the mask to create patterns on the photosensitive layer. The photosensitive layer is then exposed to an intense light where there are openings in the mask. On the other hand, some portions of the wafer may be masked so that the light does not contact the photosensitive layer. However, the portions of the wafer that are exposed to the light undergo a reaction that allows those portions to be removed in subsequent steps. In some instances, the light that is irradiated onto the mask experiences diffraction while passing through slits and spaces of the mask, which is an effect that may limit the design of the circuit on the wafer. The diffraction effect is one limit on the level of detail that may be achieved for a circuit. At a certain level of detail, the size of openings in the mask is limited by the size of the wavelength of the light being used. In addition, the exposure from the light may affect the photosensitive layer differently depending on the chemical properties of materials (i.e., varying chemical properties) of the photosensitive layer.

Thus, the diffraction effect may cause the desired pattern to change and in some instances, the change to the pattern's form due to the diffraction effect may be predicted by an optical model. That is, it may be possible to design the mask in a manner to account for the diffraction effect when using small detail sizes.

Furthermore, the change to the pattern's form due to the varying chemical properties may be predicted by a resist model. The modifying of the mask's design may be performed in an inverse manner by performing an inverse modeling of the predicted model, and a layout pattern that generates a desired pattern may be created. The process of modifying the mask's design layout form to create the desired pattern, by accounting for the diffraction effect and the chemical variation, may be accomplished by modeling optical and resist properties which may be called optical proximity correction (OPC).

The OPC may be performed using deep learning (e.g., by employing a neural network), but a forward model without errors should first be secured to accurately perform the OPC. An example of a conventional method that performs modeling optical and resist models may include a rigorous model and a compact model. The rigorous model may perform relatively accurate modeling, but it has a disadvantage of taking too long, and thus the rigorous model is rarely used except for special purposes. On the other hand, the compact model may perform the optical modeling and resist modeling in a relatively simple manner and while also being able to perform the modeling in a short amount of time.

Referring to FIG. 1, an aerial image (AI) is an image of light transmitted from a mask pattern onto the wafer. The AI may represent a process by which light is reflected or refracted when the light passes through the mask and reaches the wafer and may provide information related to the formation of a semiconductor pattern, which is the final result of the exposure process. The AI may be referred to as an aerial image, spatial image, region image, etc.

The RI is an image formed by placing a resist, a light-sensitive material, on the wafer and irradiating exposure light during the exposure process. The RI may be changed depending on the properties of resist materials when light passes through an exposure mask and is transmitted onto the wafer, and the changed image may be used in the process of protecting or removing the resist materials from a certain portion of the wafer.

The compact model may be divided into an optical simulation and a resist simulation. The optical simulation of predicting an AI from a mask image (MI) (hereinafter, may be referred to as a mask pattern) including a circuit pattern may perform approximation in a sum of coherent system (SOCS) manner. The resist simulation of predicting a resist image (RI) from the AI may perform modeling of a post exposure bake (PEB) in which a photoresist that receives light reacts, and may be approximated by a linear combination of kernel sets due to a difficulty in mathematical modeling.

As described above, in creating the forward model of OPC, an existing rigorous model may have an extremely high accuracy, but again, it is difficult to employ the existing rigorous model because of its complexity and the amount of time it requires to develop. Because the compact model is relatively fast and designs each kernel based on physical and chemical phenomena, the compact model has an advantage of being well generalized even when a database (DB) used for optimizing the kernel set is relatively small. In practice, the optical model may be approximated with relatively high accuracy, while the resist model is known to have significantly lower level of accuracy for its approximation. Thus, a more complex model may be desired to simulate the PEB for a negative tone development (NTD) process and an extreme ultraviolet (EUV) process.

In an example, a feed forward model may use the physical modeling of the compact model and perform a training of an image-to-image method to perform modeling of unknown physical phenomena that are not captured or anticipated by the existing compact model. Furthermore, the feed forward model may estimate the position and shape of a pattern in addition to the size of the pattern included in the MI.

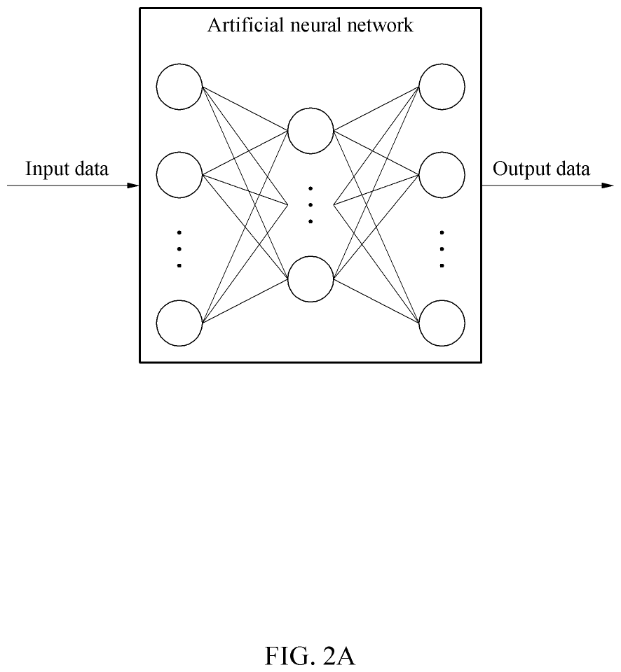

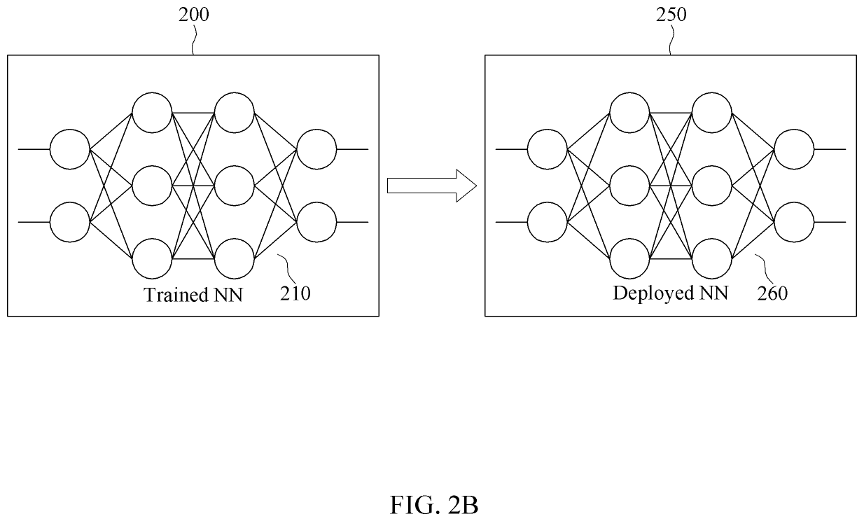

FIG. 2A illustrates an example deep learning operation method using an artificial neural network (ANN) according to one or more embodiments.

In an example, a machine learning model including a deep learning technique may input data to a NN, train the NN with output data through operations such as convolution and feature extracting of the trained NN. In the NN, nodes are connected to each other and collectively operate to process the input data. Various types of neural networks may include, for example, a convolutional neural network (CNN), a recurrent neural network (RNN), a deep belief network (DBN), and a restricted Boltzmann machine (RBM) model but are not limited thereto. In a feed-forward neural network, nodes of one layer of the neural network may have links to other nodes of a next layer. Such links may extend through the neural network in one direction, for example, in a forward direction.

Referring to FIG. 2A, in an example, a structure of the NN (e.g., the CNN) that is provided input data and outputs output data. In an example, the NN 220 may be a deep neural network including two or more layers.

FIG. 2B illustrates an example system for estimating the RI according to one or more embodiments.

Referring to FIG. 2B, in a non-limiting example, an RI estimation system may include a training device 200 and an inference device 250. The training device 200 may be a computing device having various processing functions, such as generating a neural network, training (or learning) the neural network, or retraining the neural network. For example, the training device 200 may be various devices as, for example, a personal computer (PC), a server device, or a mobile device.

The training device 200 may generate at least one trained neural network 210 by repetitively training (or learning) a given initial neural network. The generating of at least one trained neural network 210 may refer to determining neural network parameters. Here, the neural network parameters may include various types of data input/output (I/O) to/from the neural network and inputs and outputs of the layers of the neural network, weight and bias of the neural network, e.g., where the weights may correspond to respective weighted connections from nodes of one layer to one node of another layer, or of recurrent connections. Each node of the one layer may receive activations from multiple nodes of a previous layer through such weighted connections. Parameters may include hyper parameters with information of the architecture of the network, e.g., including information on the various types of data I/O to/from the neural network and inputs and outputs of the layers of the neural network. When the neural network is repeatedly (iteratively) trained, the parameters of the neural network may be adjusted and tuned to calculate a more accurate output for a given input.

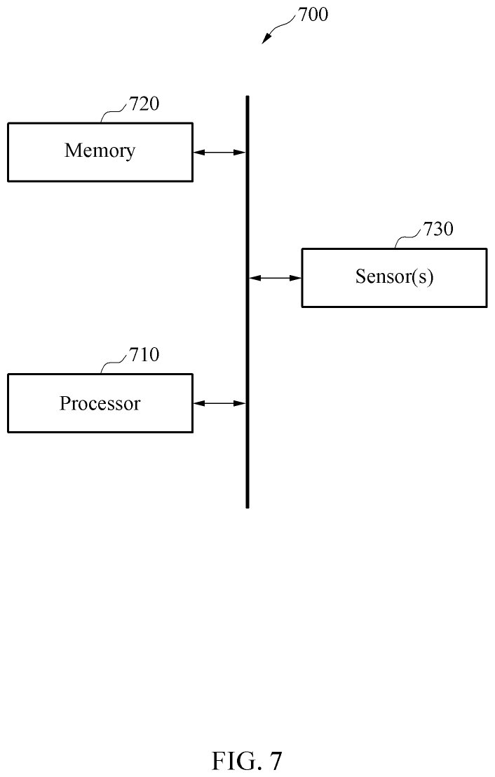

The training device 200 may transmit at least one trained neural network 210 to the inference device 250. In an example, the inference device 250 may be, for example, a mobile device or an embedded device. In an example, the inference device 250 may be a piece of hardware dedicated for implementing the neural network (or at least a portion of the neural network). In such examples, inference device 250 may be an electronic device including at least one of a processor, a memory, an I/O interface, a display, a communication interface, or a sensor of such a mobile device or embedded device. For example, the sensor may include at least one camera and/or other imaging sensors to capture images of scenes. In another example, the sensor may include the sensors 730 of FIG. 7.

The inference device 250 may be any digital device that has a memory element and a microprocessor with an operational capability, such as a tablet PC, a smartphone, a PC (e.g., a laptop computer), an AI speaker, a smart television (TV), a mobile phone, a navigation, a web pad, a personal digital assistant (PDA), and a workstation. Hereinafter, the inference device 250 may also be referred to as a final image generation apparatus.

In a non-limiting example, the inference device 250 may drive at least one trained neural network 210 without any change or may drive a neural network 260 to which at least one trained neural network 210 is processed (e.g., quantized). The inference device 250 driving the processed neural network 260 may be implemented in a device separate from the training device 200. In an example, the inference device 250 may also be implemented in the same device as the training device 200.

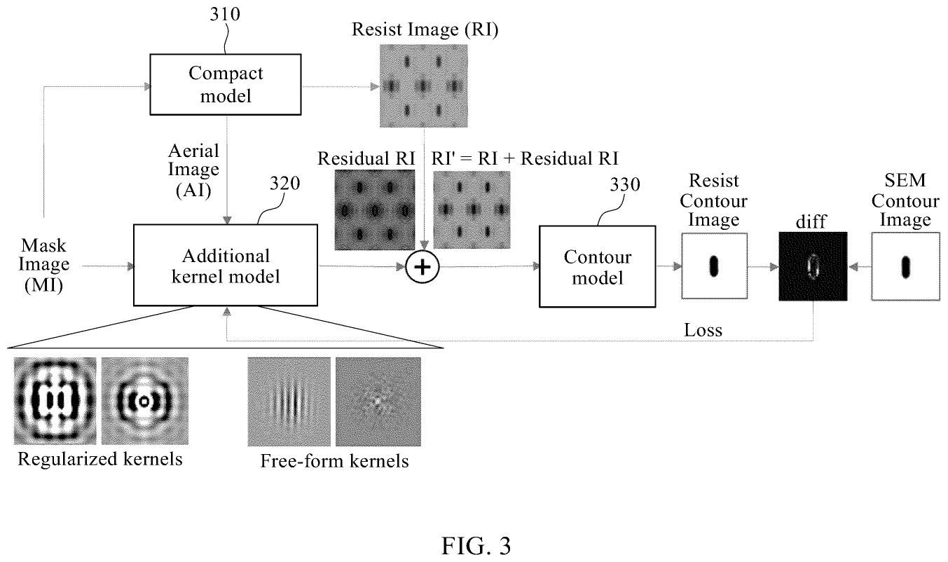

FIG. 3 illustrates an example method of training a feed forward model according to one or more embodiments.

Referring to FIG. 3, in an example, the feed forward model may perform modeling of the resist model by adding a kernel additionally found by deep learning while using the physical model-based kernel of the conventional compact model up to the n-th kernel as shown in Equation 1 below.

$${R}^{′} ( x , y ) = {\underbrace{{c}_{0} I ( x , y ) ) + {c}_{1} I ( x , y ) ⊗ {G}_{1} ( {σ}_{1} ) + … +}}_{R ( x , y )} ML filter kernel [ {c}_{\text{?}} \vert ( x , y ) ⊗ {K}_{\text{?}} + {c}_{\text{?}} \vert ( x , y ) ⊗ {K}_{\text{?}} + … ] \qquad Equation 1$$

$$\text{?} \text{indicates text missing or illegible when filed}$$

Because the number of existing kernels and the number of kernels of the new feed forward model may be configurable parameters, in some cases, there may be one to an infinite number of kernels of the feed forward model being used. The kernels based on the physical modeling of the conventional compact model may not be used at all or may be used countless times.

While Equation 1 illustrates an example using a single layered linear kernel, the function is not limited thereto, and a multi-layered function including an activation function may be applied to an input AI I(x, y) or an MI M(x, y).

In a non-limiting example, the feed forward model may include a compact model 310, an additional kernel model 320, and a contour model 330. The compact model 310 may generate the AI and RI from the MI, using, for example, the optical model and resist model of the conventional compact model. The RI generated through the compact model 310 may be referred to as a first RI.

In an example, the additional kernel model 320 may receive the AI and generate a residual RI from the trained kernel, and the residual RI may be referred to as a second RI. The MI may be also selectively used as an input of the trained kernel of the additional kernel model 320.

In an example, an RI′ with less error may be generated by adding the RI generated through the compact model 310 to the residual RI generated through the additional kernel model 320, which is referred to as a third RI.

The contour model 330 (e.g., a contour network) may generate a resist contour image (RCI) from the third RI. Furthermore, the feed forward model may obtain a contour image (hereinafter, referred to as a scanning electron microscope (SEM) contour image) obtained through the SEM. An SEM image may be generated by measuring an MI with the SEM, and an SEM contour may be generated by extracting a contour from the SEM image. The SEM contour is figure information represented as coordinates, and an SEM contour image may be generated from the SEM contour through a graphics algorithm.

The feed forward model may train the additional kernel model 320 based on a difference between the RCI and the SEM contour image. The feed forward model may train the additional kernel model 320 so that the difference between the RCI and the SEM contour image is minimized. The training of the additional kernel model 320 may refer to training a parameter and a coefficient of the kernel included in the additional kernel model 320.

The existing kernels of the compact model 310 may also be trained so that the difference between the RCI and the SEM contour image is selectively minimized.

The reason for training method to reduce errors between the RCI and the SEM contour image is that a measured SEM image is difficult to use directly because the measured SEM image has too much noise and intensity varies significantly depending on the angle of capturing an image. Therefore, the feed forward model may extract a contour from the SEM image and use a dithered SEM contour image.

Here, because the conventional contour dither algorithm for obtaining the RCI is not differentiable, it may be difficult to perform backpropagation. The contour model 330 may be an ANN model capable of performing backpropagation and may be trained in advance to receive the RI (e.g., the third RI) and estimate the RCI. For example, the contour model 330 may be a CNN-based model. However, the contour model 330 is not limited to an ANN model. The contour model 330 may be implemented as various models that may estimate a contour of an image. For example, the contour model 330 may be an algorithm-based model that estimates the contour of the image.

That is, the contour model 330, which is pre-trained using a pair of the RI and RCI, may be fixed and kernel training of the additional kernel model 320 may be performed based on information backpropagated from the contour model 330.

Furthermore, since the feed forward model performs training of the additional kernel model 320 through an image-to-image method, the additional kernel model 320 may reflect the position and shape of the pattern in addition to the size of the pattern formed on the wafer that is generated by the MI.

More specifically, when kernel optimization is determined based on the difference between a critical dimension (CD) obtained from the SEM contour that is obtained through measurement and a CD obtained from an estimated register contour, the corresponding model may not reflect a pattern shift and not estimate the shape of the pattern.

On the other hand, the feed forward model may perform training of the additional kernel model 320 based on the difference between the SEM contour image and the RCI including shape information of the pattern formed on the wafer that is generated by the MI. That is, the additional kernel model 320 may be trained by considering the shape of the pattern and pattern shift in addition to the size of the pattern formed on the wafer that is generated by the MI.

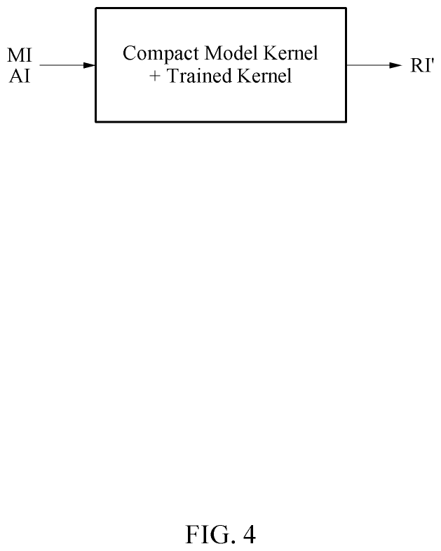

FIG. 4 illustrates an example method of estimating the RI according to one or more embodiments.

The description provided with reference to FIG. 3 may be similar to the description of FIG. 4, and thus, where appropriate, a duplicate description is omitted.

Referring to FIG. 4, an inference device (e.g., the inference device 250 in FIG. 2B) may estimate the RI using a trained compact model (e.g., the compact model 310 in FIG. 3) and an additional kernel model (e.g., the additional kernel model 320 in FIG. 3).

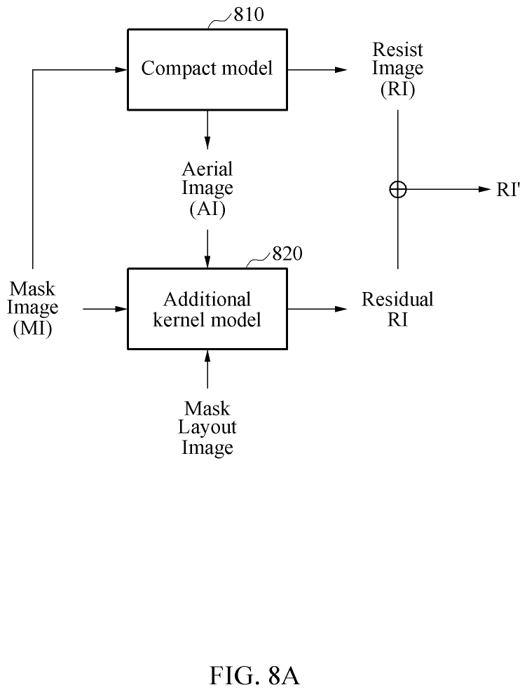

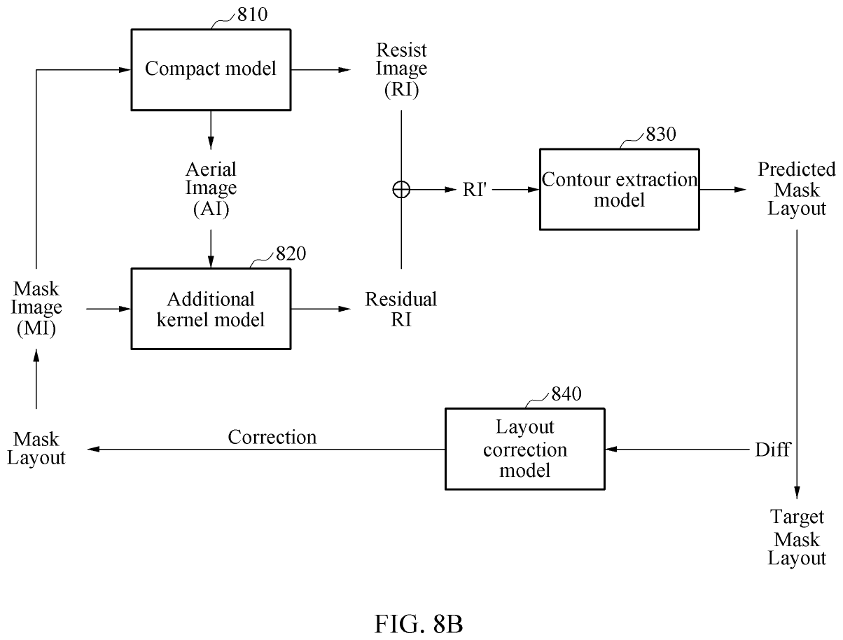

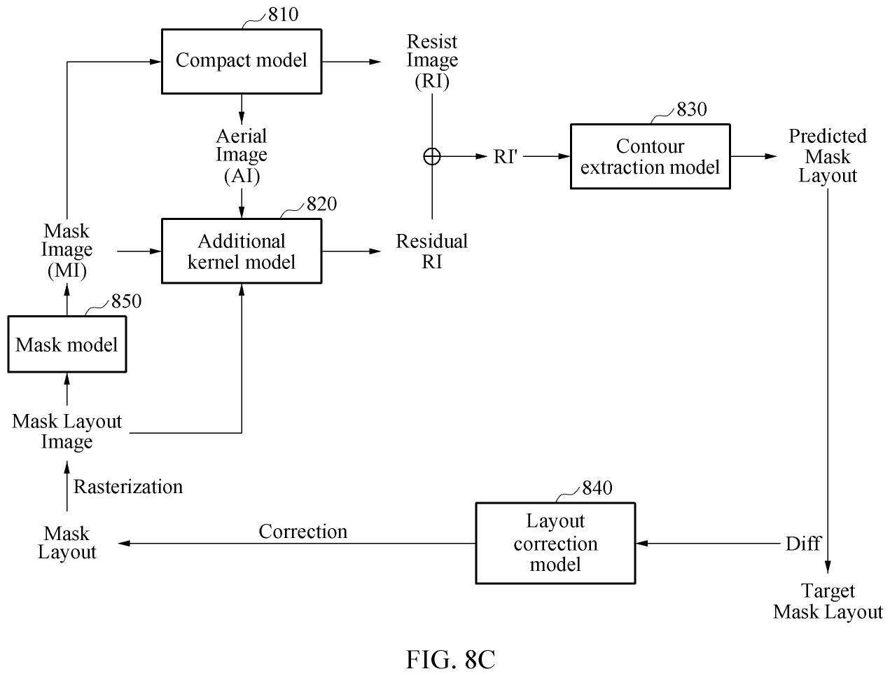

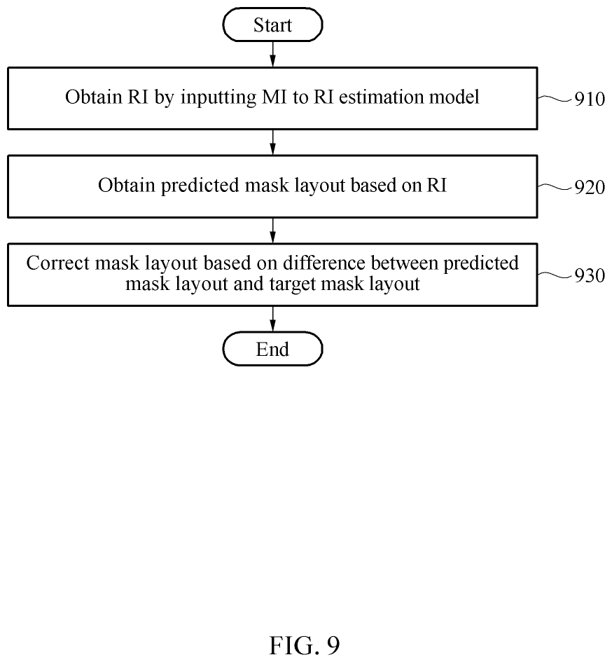

In operation 410, the compact model may receive the MI and obtain the AI and the first RI. The additional kernel model may receive the AI and obtain the second RI (the residual RI). The third RI (RI′) may be generated by adding the first RI to the second RI. The method of estimating the RI is described in detail below with reference to FIGS. 8A to 9.

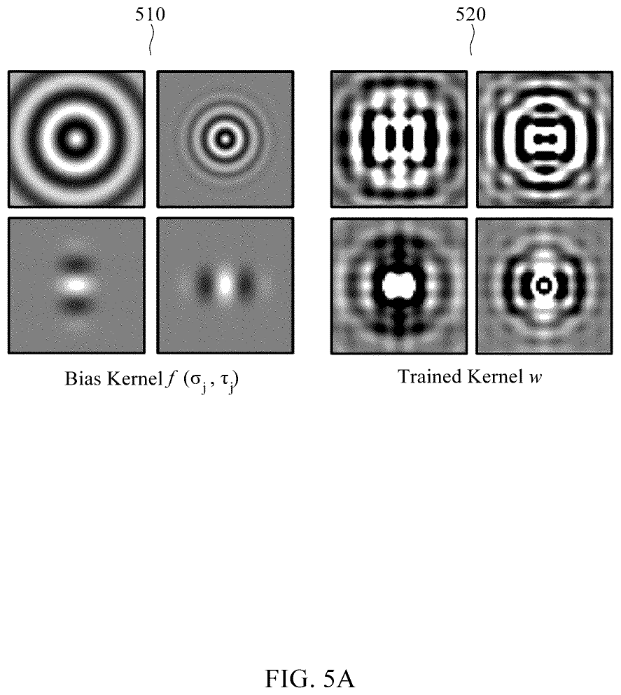

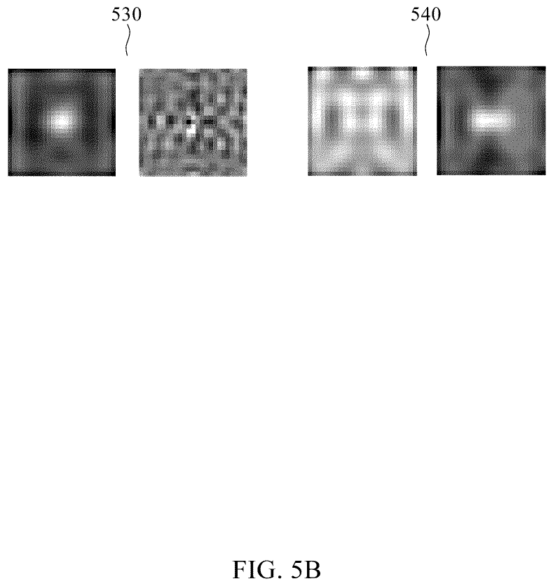

FIGS. 5A and 5B illustrate examples kernels of the additional kernel model according to one or more embodiments.

Referring to FIG. 5A, in a non-limiting example, when training the additional kernel model (e.g., the additional kernel model 320 of FIG. 3), the kernel may be created without limitation in a free-form, but a regularized kernel may also be used to prevent overfitting. The additional kernel model may use a method of combining bias kernels to generate the regularized kernel.

In an example, the additional kernel model may configure the kernel in a form of passing the activation function after applying the regularized kernel to the AI and the MI according to Equation 2.

$$\begin{matrix}{RI}_{residual} = {\sum }_{i} {k}_{i} \cdot [ sigmoid ( {w}_{i}^{mi} * ( {x}_{mi} - 0.5 ) + {w}_{i}^{ai} * ( {x}_{ai} - 0.5 ) ) ] \\ {w}_{i}^{n} = {\sum }_{j} {α}_{i , j}^{n} f ( {σ}_{x} , {σ}_{y} , τ ) , {α}_{i , j}^{n} ∈ ℝ , f ∈ \{ {f}_{xy} , {f}_{xy} , {f}_{xy} , {f}_{bias} \} , \\ {f}_{xy} ( {σ}_{x} , {σ}_{y} , τ ) = {e}^{- ( \frac{{x}^{2}}{2 {σ}_{x}^{2}} + \frac{{y}^{2}}{2 {σ}_{y}^{2}} )} cos ( \sqrt{{x}^{2} + {y}^{2}} π τ ) , \\ {f}_{xx} ( {σ}_{x} , {σ}_{y} , τ ) = {e}^{- ( \frac{{x}^{2}}{2 {σ}_{x}^{2}} + \frac{{y}^{2}}{2 {σ}_{y}^{2}} )} cos ( x π τ ) , \\ {f}_{yy} ( {σ}_{x} , {σ}_{y} , τ ) = {e}^{- ( \frac{{x}^{2}}{2 {σ}_{x}^{2}} + \frac{{y}^{2}}{2 {σ}_{y}^{2}} )} cos ( y π τ ) , \\ {f}_{bias} ( {σ}_{x} , {σ}_{y} τ ) = 1.\end{matrix} \qquad Equation 2$$

In an example, the additional kernel model may configure a bias kernel 510 as a combination of Gabor filters (i.e., a Gabor kernel). A Gabor kernel may be composed of a form in which positive and negative values of the kernel appear periodically, and by adjusting the period, the additional kernel model may generate various types of kernels. In addition, a combination of the kernels ensuring rotational symmetry may exist in the Gabor kernel. Thus, kernel 520 may be generated to create horizontal or vertical symmetry in a form of horizontal and vertical stripes.

Referring to FIG. 5B, in a non-limiting example, the free-form kernel may perform training without restrictions on the kernel form so that the characteristics of data may be expressed as much as possible, and the data may be overfit during training with random initialization and thus it is easy to show an arbitrary characteristic of the kernel form. Accordingly, the additional kernel model may train the free-form kernel by initializing a training kernel in a Gaussian form and drawing 530 may be an example of the kernel trained in the free-form form.

In an example, it is possible to train the kernel to generate a symmetrical form even when employing the free-form kernel. In a non-limiting example, Equation 3 is an equation for training the kernel that ensures horizontal or vertical symmetry by applying reflection symmetry, and drawing 540 may be an example of the kernel trained based on Equation 3. Equation 3:

RI_{residual}=αₕ[σ(wₕ*L)+σ(_{hflip}(wₕ)*I)]+αᵥ[σ(wᵥ*I)+σ(vflip(wᵥ)*I)]

The free-form kernel is difficult to train when the kernel size is large during training and it has a characteristic that it is sensitive to initialization. Accordingly, the additional kernel model may prevent overfitting by stacking a plurality of kernels using a deep linear generator and training.

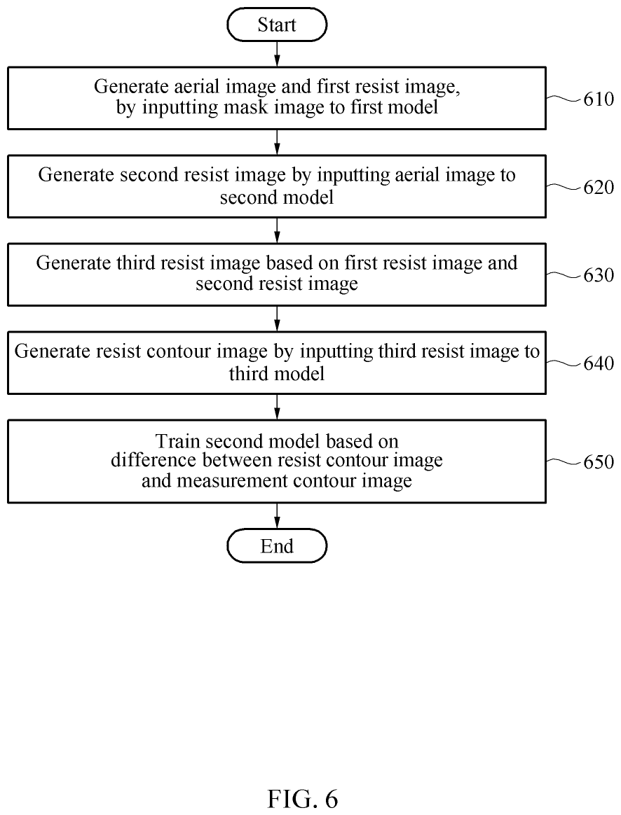

FIG. 6 illustrates an example training method according to one or more embodiments.

For ease of explanation, operations 610 to 650 are described as being performed using the training device 200 shown in FIG. 2B. However, operations 610 and 650 may be performed by another suitable electronic device in a suitable system (e.g., processor 710 of FIG. 7).

Furthermore, operations 610 to 650 of FIG. 6 may be performed in the shown order and manner. However, the order of some operations may be changed or omitted without departing from the spirit and scope of the shown example. The operations illustrated in FIG. 6 may be performed in parallel or simultaneously.

Referring to FIG. 6, in a non-limiting example, in operation 610, the training device may generate the AI and the first RI, by inputting the MI to the first model. As described above, the first model may be the compact model.

In operation 620, the training device may generate the second RI by inputting the AI to the second model. The training device may generate the second RI by inputting not only the AI but also the MI to the second model. The second model may be the additional kernel model as described above, and the second RI may be the residual RI.

In operation 630, the training device may generate the third RI based on the first RI and the second RI. For example, the training device may generate the third RI by adding the first RI to the second RI and the third RI may be the RI′ with improved accuracy.

In operation 640, the training device may generate the RCI by inputting the third RI to the third model. As described above, the third model may be the contour model.

In operation 650, the training device may train the second model based on the difference between the RCI and the measurement contour image. The training device may train the second model so that the difference is minimized using information obtained through backpropagation of the third model. The training device may train the parameter and the coefficient of the kernel included in the second model. The third model may be fixed while the training device trains the second model.

The third model may be the CNN-based model that receives the third RI and generates the RCI. The third model may be trained based on the third RI and the measurement contour image.

FIG. 7 illustrates an example configuration of an electronic device according to one or more embodiments.

Referring to FIG. 7, an electronic device 700 may include at least one processor 710, a memory 720, a sensor(s) 730, an imaging device 740 (e.g., a display), and a communications interface (e.g., an I/O interface) 750. The description provided with reference to FIGS. 3 to 6 may also be applied to FIG. 7. For example, the electronic device 700 may be the training device 200 described with reference to FIG. 2.

The processor 710 may be configured to execute programs or applications to configure the processor 710 to control the electronic device 700 to perform one or more or all operations and/or methods involving the resist imaging and training of the neural networks, and may include any one or a combination of two or more of, for example, a central processing unit (CPU), a graphic processing unit (GPU), a neural processing unit (NPU) and tensor processing units (TPUs), but is not limited to the above-described examples. The processor 710 may also execute programs or applications to control other functionalities of the electronic device.

The memory 720 may include computer-readable instructions. The processor 710 may be configured to execute computer-readable instructions, such as those stored in the memory 720, and through execution of the computer-readable instructions, the processor 710 is configured to perform one or more, or any combination, of the operations and/or methods described herein. The memory 720 may be a volatile or nonvolatile memory.

The memory 720 may include, for example, random-access memory (RAM), dynamic random-access memory (DRAM), static random-access memory (SRAM), or other types of non-volatile memory known in the art. The memory 720 may store a pre-trained ANN model.

In a non-limiting example, the sensor(s) 730 may include an SEM, a transmission electron microscope (TEM), and a scanning probe microscope (SPM). However, examples are not limited thereto.

The display device 740 may be implemented using a liquid crystal display (LCD), a light-emitting diode (LED) display, a plasma display panel (PDP), a screen, a terminal, or any other type of display configured to display the images and information to be displayed by the image display apparatus. A screen may be a physical structure that includes one or more hardware components that provide the ability to render a user interface and receive user input. The screen may include any combination of a display region, a gesture capture region, a touch-sensitive display, and a configurable area. The screen may be part of an apparatus, or may be an external peripheral device that is attachable to and detachable from the apparatus. The display may be a single-screen display or a multi-screen display. A single physical screen may include multiple displays that are managed as separate logical displays permitting different content to be displayed on separate displays even though they are part of the same physical screen.

The communication interface 750 (e.g., an I/O interface) may include user interface may provide the capability of inputting and outputting information regarding training device 200, the electronic device 700, and other devices. The communication interface 750 may include a network module for connecting to a network and a module for forming a data transfer channel with a mobile storage medium. In addition, the user interface may include one or more input/output devices, such as the display device 750, a mouse, a keyboard, a speaker, or a software module for controlling the input/output device.

The processor 710 may obtain the AI and the first RI, by inputting the MI to the first model, obtain the second RI by inputting the AI to the second model, obtain the third RI based on the first RI and the second RI, generate the RCI by inputting the third RI to the third model, and train the second model based on the difference between the RCI and the measurement contour image.

FIG. 8A illustrates an example of a method of estimating an RI.

Referring to FIG. 8A, an inference device (e.g., the inference device 250 in FIG. 2B) may receive an MI and estimate an RI corresponding to the MI. The inference device may estimate the RI using the feed forward model trained according to the training method described with reference to FIG. 3. For example, a compact model 810 may include the compact model 310 of FIG. 3 and an additional kernel model 820 may include the additional kernel model 320 of FIG. 3.

The inference device may obtain an AI and the RI (the first RI) from the MI. For example, the inference device may obtain the AI and the RI (the first RI) by inputting the MI to the compact model 810.

The inference device may obtain a residual RI (the second RI) from the AI. For example, the inference device may obtain the residual RI (the second RI) by inputting the AI to the additional kernel model 820. In addition, the inference device may obtain the residual RI (the second RI) by inputting the MI and/or a mask layout image to the additional kernel model 820 together with the AI.

The additional kernel model 820 may be trained by considering the shape of a pattern and pattern shift in addition to the size of the pattern included in the MI. Accordingly, the additional kernel model 820 may estimate the shape of the pattern in addition to the size of the pattern included in the MI.

The inference device may obtain the third RI (RI′) based on the RI (the first RI) and the residual RI (the second RI). For example, the inference device may obtain the third RI (RI′) by combining the RI (the first RI) with the residual RI (the second RI). The third RI (RI′) may include shape information of the pattern formed on the wafer that is generated by the MI.

FIGS. 8B and 8C illustrate examples of a method of manufacturing a mask.

The description provided with reference to FIG. 8A may be applied to FIGS. 8B and 8C. For example, the method of manufacturing a mask of FIGS. 8B and 8C may use the third RI (RI′) described with reference to FIG. 8A.
A contour extraction model 830 may generate a predicted mask layout based on the third RI. The predicted mask layout may include, for example, an RCI generated from the third RI. The contour extraction model 830 may generate the RCI from the third RI. The contour extraction model 830 may be the contour model 330 described with reference to FIG. 3 but is not limited thereto, and the contour extraction model 830 may include various models capable of extracting a contour of an image.
A layout correction model 840 may correct a mask layout based on the difference between the predicted mask layout and a target mask layout. The layout correction model 840 may correct the mask layout so that the difference between the predicted mask layout and the target mask layout is reduced. The layout correction model 840 may be a rule-based algorithm model or an ANN-based model.
A layout image that is rasterized from the mask layout may be generated, and using the rasterized layout image as a new MI, the process of re-estimating the third RI (RI′), correcting the predicted mask layout and mask layout, and generating the rasterized layout image may be repeated until a predetermined condition is satisfied. For example, the above-described operation may be repeated until the difference between the predicted mask layout and the target mask layout becomes less than or equal to a predetermined critical value.
Referring to FIG. 8C, instead of using the rasterized mask layout image as the new MI, an MI in which a three-dimensional (3D) element is reflected may be used as the new MI by inputting the rasterized mask layout image to a mask model 850 and generating the MI in which the 3D element is reflected. An actual mask is a 3D mask but the MI is a two-dimensional (2D) image.
Accordingly, the mask model 850 may generate a 2D MI in which the 3D element of the mask (e.g., the thickness of the mask) is reflected.

FIG. 9 illustrates an example of a method of manufacturing a mask.

For the convenience of description, operations 910 to 930 are described as being performed using the inference device 250 shown in FIG. 2B. However, operations 910 to 930 may be performed by another suitable electronic device and in a suitable system. For example, operations 910 to 930 may be performed by a mask manufacturing device.
Furthermore, the operations of FIG. 9 may be performed in the shown order and manner. However, the order of some operations may be changed, or some operations may be omitted, without departing from the spirit and scope of the shown example. The operations shown in FIG. 9 may be performed in parallel or simultaneously.
Referring to FIG. 9, in operation 910, the inference device may obtain the RI by inputting the MI to an RI estimation model. The RI estimation model may include the compact model 810 and the additional kernel model 820 described with reference to FIGS. 8A and 8B. The RI estimation model may estimate the shape of the pattern included in the MI.
In operation 920, the inference device may obtain the predicted mask layout based on the RI. The RI may include shape information of the pattern formed on the wafer that is generated by the MI.
In operation 930, the inference device may correct a mask layout based on the difference between the predicted mask layout and a target mask layout. The mask layout may refer to a design mask layout used for manufacturing a mask. By repeating operations 910 to 930, an optimal mask layout may be determined. For example, operations 910 to 930 may be repeated until the difference between the predicted mask layout and the target mask layout becomes less than or equal to a predetermined critical value.

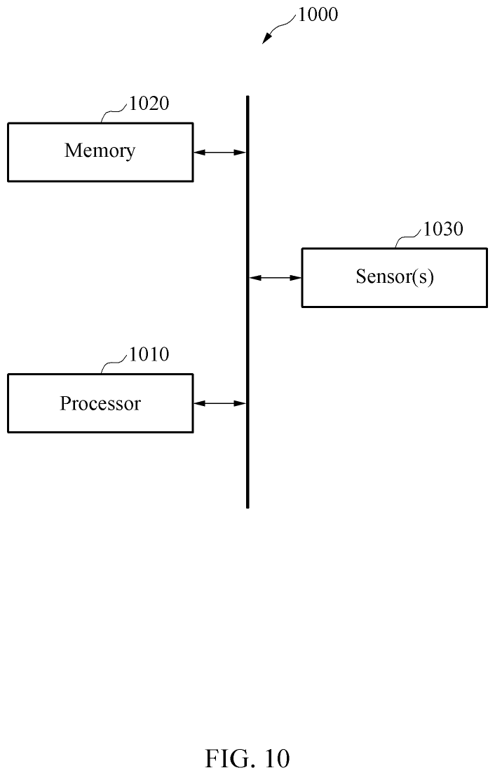

FIG. 10 illustrates an example of a configuration of an electronic device.

Referring to FIG. 10, an electronic device 1000 may include at least one processor 1010, a memory 1020, and sensor(s) 1030. The electronic device 1000 may be the inference device 250 described with reference to FIG. 2.
The memory 1020 may store instructions that may be read by a computer. When the instructions stored in the memory 1020 are executed by the processor 1010, the processor 1010 may process operations defined by the instructions. The memory 1020 may include, for example, RAM, DRAM, SRAM, or other types of non-volatile memory known in the art. The memory 1020 may store a pre-trained ANN model.
The sensor(s) 1030 may include an SEM, a TEM, and an SPM. However, examples are not limited thereto. Since one having ordinary skill in the art may intuitively infer the function of each sensor from its name, a detailed description thereof is omitted.

The at least one processor 1010 may control the overall operation of the electronic device 1000. The processor 1010 may be a hardware-implemented apparatus having a circuit that is physically structured to execute desired operations. The desired operations may include code or instructions included in a program. The hardware-implemented apparatus may include, but is not limited to, for example, a microprocessor, a CPU, a GPU, a processor core, a multi-core processor, a multiprocessor, an application-specific integrated circuit (ASIC), a field-programmable gate array (FPGA), and an NPU.

The processor 1010 may obtain the AI and the first RI from the MI, obtain the second RI by inputting the AI to the additional kernel model, and obtain the third RI based on the first RI and the second RI. The additional kernel model may estimate the shape of the pattern included in the MI.

The neural networks, processors, memories, electronic devices, electronic device 700, processor 710, memory 720, sensors 730, ANN 220, inference device 250, training device 200, neural networks 210 and 260, described herein and disclosed herein described with respect to FIGS. 1-7 are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-7 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RW, DVD-RAMs, BD-ROMs, BD-Rs, BD-R LTHs, BD-Res, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A method of estimating a resist image (RI), the method comprising:
obtaining an aerial image (AI) and a first RI from a mask image (MI);
obtaining a second RI by inputting the AI to an additional kernel model; and
obtaining a third RI based on the first RI and the second RI,
wherein the third RI comprises shape information of a pattern formed on a wafer that is generated by the MI.

2. The method of claim 1, wherein the obtaining of the AI and the first RI comprises obtaining the AI and the first RI by inputting the MI to a compact model.

3. The method of claim 1, wherein the obtaining of the third RI comprises obtaining the third RI by combining the first RI with the second RI.

4. The method of claim 1, wherein the additional kernel model is trained based on a difference between a resist contour image (RCI) generated based on the third RI and a measurement contour image generated through measurement.

5. The method of claim 4, wherein the additional kernel model is trained so that the difference is minimized through backpropagation.

6. The method of claim 1, further comprising:
obtaining a predicted mask layout based on the third RI; and
correcting a mask layout based on a difference between the predicted mask layout and a target mask layout.

7. The method of claim 6, wherein the obtaining of the predicted mask layout further comprises:
generating an RCI from the third RI; and
obtaining the predicted mask layout based on the RCI.

8. The method of claim 6, wherein the correcting of the mask layout further comprises:
correcting the mask layout based on the difference between the predicted mask layout and the target mask layout; and
obtaining a mask layout image that is rasterized from the corrected mask layout.

9. The method of claim 8, further comprising:
generating an MI in which a three-dimensional (3D) element is reflected by inputting the mask layout image to a mask model.

10. A method of manufacturing a mask, the method comprising:
obtaining a resist image (RI) by inputting a mask image (MI) to an RI estimation model;
obtaining a predicted mask layout based on the RI; and
correcting a mask layout based on a difference between the predicted mask layout and a target mask layout,
wherein the RI comprises shape information of a pattern formed on a wafer that is generated by the MI.

11. A non-transitory computer-readable storage medium storing instructions that, when executed by a processor, cause the processor to perform the method of claim 1.

12. An electronic device comprising:
a memory storing at least one instruction; and
a processor configured to, by executing the at least one instruction stored in the memory:
obtain an aerial image (AI) and a first resist image (RI) from a mask image (MI);
obtain a second RI by inputting the AI to an additional kernel model; and
obtain a third RI based on the first RI and the second RI,
wherein the third RI comprises shape information of a pattern formed on a wafer that is generated by the MI.

13. The electronic device of claim 12, wherein the processor is configured to obtain the AI and the first RI by inputting the MI to a compact model.

14. The electronic device of claim 12, wherein the processor is configured to obtain the third RI by combining the first RI with the second RI.

15. The electronic device of claim 12, wherein the additional kernel model is trained based on a difference between a resist contour image (RCI) generated based on the third RI and a measurement contour image generated through measurement.

16. The electronic device of claim 15, wherein the additional kernel model is trained so that the difference is minimized through backpropagation.

17. The electronic device of claim 15, wherein the processor is configured to:
obtain a predicted mask layout based on the third RI; and
correct a mask layout based on a difference between the predicted mask layout and a target mask layout.

18. The electronic device of claim 17, wherein the processor is configured to:
generate the RCI from the third RI; and
obtain the predicted mask layout based on the RCI.

19. The electronic device of claim 17, wherein the processor is configured to:
correct the mask layout based on the difference between the predicted mask layout and the target mask layout; and
obtain a mask layout image that is rasterized from the corrected mask layout.

20. The electronic device of claim 19, wherein the processor is configured to generate an MI in which a three-dimensional (3D) element is reflected by inputting the mask layout image to a mask model.
